(19) United States
(12) Patent Application Publication
(10) Pub. No.: US 2023/0006045 A1
(43) Pub. Date: Jan. 5, 2023

(54) SILICON CARBIDE SEMICONDUCTOR DEVICE AND METHOD FOR MANUFACTURING SILICON CARBIDE SEMICONDUCTOR DEVICE

(71) Applicant: Mitsubishi Electric Corporation, Tokyo (JP)

(72) Inventors: Naoyuki KAWABATA, Tokyo (JP); Yuichi NAGAHISA, Tokyo (JP); Takanori TANAKA, Tokyo (JP); Toshiaki IWAMATSU, Tokyo (JP)

(73) Assignee: Mitsubishi Electric Corporation, Tokyo (JP)

(21) Appl. No.: 17/781,737

(22) PCT Filed: Jan. 27, 2020
(86) PCT No.: PCT/JP2020/002717

§ 371 Date: Jun. 2, 2022

(51) Int. Cl. H01L 29/16; H01L 29/868; H01L 21/265; H01L 29/78

(52) U.S. Cl. CPC H01L 29/1608; H01L 29/868; H01L 21/26513; H01L 29/7804

(57) ABSTRACT

The present disclosure has an object of providing a silicon carbide semiconductor device with high productivity which prevents characteristic degradation occurring when a large current is applied to a body diode. A structure including a SiC substrate, a buffer layer, and a drift layer is classified into an active region through which a current flows with application of a voltage to the SiC-MOSFET, and a breakdown voltage support region around a periphery of the active region in a plan view. The active region is classified into a first active region in a center portion, and a second active region between the first active region and the breakdown voltage support region in the plan view. Lifetimes of minority carriers in the second active region and the breakdown voltage support region are shorter than that in the first active region.

### TECHNICAL FIELD

The present disclosure relates to a silicon carbide semiconductor device.

### BACKGROUND ART

It is known that continuously passing a forward current, specifically, a bipolar current through a p-n diode made of silicon carbide (SiC) creates a problem in the reliability, that is, stacking faults in crystals which cause a forward voltage to shift. This probably occurs due to expansion of the stacking faults, specifically, plane defects with recombination energy obtained when minority carriers injected through the p-n diode recombine with majority carriers. The expansion originates from, for example, a basal plane dislocation in a silicon carbide substrate. The stacking faults obstruct the current flow. Hence, the expansion of the stacking faults reduces the current and increases the forward voltage, thus causing reduction in the reliability of a semiconductor device.

Such increase in the forward voltage also occurs in vertical metal oxide semiconductor field effect transistors (MOSFETs) made of silicon carbide. Each of the vertical MOSFETs includes a parasitic p-n diode (body diode) between a source and a drain. When the forward current flows through this body diode, the reliability in the vertical MOSFETs also deteriorates similarly to the p-n diode. When a body diode of a SiC-MOSFET is used as a free-wheeling diode of a MOSFET, the characteristics of this MOSFET are sometimes degraded.

There are following three methods for solving the problem in the reliability which is caused by the passage of the forward current through the parasitic p-n diode. The first method is converting a basal plane dislocation inherited from a SiC substrate to an epitaxial growth layer into a threading edge dislocation for preventing expansion of stacking faults (for example, see Non-Patent Document 1). The second method is forming a buffer layer higher in impurity concentration on a SiC substrate and enhancing recombination of holes and electrons in the buffer layer for preventing stacking faults from a basal plane dislocation in the SiC substrate (for example, see Non-Patent Document 2). The third method is introducing a recombination center into a region with a parasitic p-n diode and reducing holes to be injected for preventing recombination of holes and electrons in the vicinity of a basal plane dislocation in a SiC substrate (for example, see Patent Document 1).

### PRIOR ART DOCUMENT

### Patent Document

Patent Document 1: WO2015/189929

### Non-Patent Documents

Non-Patent Document 1: “Influence of growth conditions on basal plane dislocation in 4H-SiC epitaxial layer”, Journal of Crystal Growth 271 (2004) 1-7

Non-Patent Document 2: “Short minority carrier lifetimes in highly nitrogen-doped 4H-SiC epilayers for suppression of the stacking fault formation in PiN diodes”, JOURNAL OF APPLIED PHYSICS Vol. 120, pp115101, 2016

### SUMMARY

### Problem to be Solved by the Invention

The technologies disclosed in Non-Patent Documents 1 and 2 produce some advantages for preventing degradation in the characteristics of a SiC-MOSFET. However, these technologies require forming a thick buffer layer for applying a large current to a body diode. This creates a problem of increase in a productivity cost. Furthermore, increase in manufacturing variations in buffer layers into which a high concentration of impurities is implanted causes a problem of decrease in the productivity.

The technology disclosed in Patent Document 1 requires formation of the recombination center in a p-n junction portion. This significantly degrades the characteristics of a body diode, and causes a problem of failing to apply a large current to the body diode.

This disclosure has been conceived to solve the problems, and has an object of providing a silicon carbide semiconductor device with high productivity which prevents characteristic degradation occurring when a large current is applied to a body diode.

### Means to Solve the Problem

The first silicon carbide semiconductor device according to the present disclosure includes: a silicon carbide substrate of a first conductivity type; a buffer layer of the first conductivity type, the buffer layer being formed on the silicon carbide substrate; a drift layer of the first conductivity type, the drift layer being formed on the buffer layer; and a well region of a second conductivity type, the well region being formed in a surface layer of the drift layer, wherein a structure including the silicon carbide substrate, the buffer layer, and the drift layer is classified into an active region through which a current flows with application of a voltage to the silicon carbide semiconductor device, and a breakdown voltage support region around a periphery of the active region in a plan view, the active region is classified into a first active region in a center portion, and a second active region between the first active region and the breakdown voltage support region in the plan view, and lifetimes of minority carriers in the second active region and the breakdown voltage support region are shorter than a lifetime of minority carriers in the first active region.

The second silicon carbide semiconductor device according to the present disclosure includes: a silicon carbide substrate of a first conductivity type; a buffer layer of the first conductivity type, the buffer layer being formed on the silicon carbide substrate; a drift layer of the first conductivity type, the drift layer being formed on the buffer layer; and a well region of a second conductivity type, the well region being formed in a surface layer of the drift layer, wherein a structure including the silicon carbide substrate, the buffer layer, and the drift layer is classified into an active region through which a current flows with application of a voltage to the silicon carbide semiconductor device, and a breakdown voltage support region around a periphery of the active region in a plan view, the active region is classified into a first active region in a center portion, and a second active region between the first active region and the breakdown voltage support region in the plan view, at least the second active region and the breakdown voltage support region among the first active region, the second active region, and the breakdown voltage support region contain inert elements, the silicon carbide semiconductor device further comprises an impurity region of the first conductivity type, the impurity region being formed in a surface layer of the well region in the active region, and the inert elements in the second active region and the breakdown voltage support region are higher in ion concentration than an inert element in the first active region.

### Effects of the Invention

The lifetimes of minority carriers in the second active region and the breakdown voltage support region are shorter than the lifetime of minority carriers in the first active region in the silicon carbide semiconductor device according to the present disclosure. This prevents the concentration of a hole current in a boundary between the second active region and the breakdown voltage support region with application of a large current to a body diode. Since the buffer layer need not be formed thicker to allow a large current to flow through the body diode, the productivity will be increased.

### BRIEF DESCRIPTION OF DRAWINGS

FIG. 1 illustrates a top view of a SiC-MOSFET according to Embodiment 1.

FIG. 2 illustrates a cross-sectional view of the SiC-MOSFET according to Embodiment 1 which is taken along the line a-a′ of FIG. 1.

FIG. 3 is a cross-sectional view illustrating a manufacturing process of the SiC-MOSFET according to Embodiment 1 which is taken along the line a-a′ of FIG. 1.

FIG. 4 is a cross-sectional view illustrating a manufacturing process of a SiC-MOSFET according to Embodiment 2 which is taken along the line a-a′ of FIG. 1.

FIG. 5 illustrates a simulation result of the hole current density distribution when a second active region is 100 μm wide in the SiC-MOSFET according to Embodiment 1.

FIG. 6 illustrates a simulation result of the hole current density distribution when the second active region is 0 μm wide in the SiC-MOSFET according to Embodiment 1.

FIG. 7 illustrates a ratio of a hole current density in the vicinity of a boundary between an active region and a breakdown voltage support region to a hole current density in the center of the active region when the width of the second active region and the lifetime of minority carriers in the second active region are changed.

### DESCRIPTION OF EMBODIMENTS

### A. Embodiment 1

### A-1. Structure

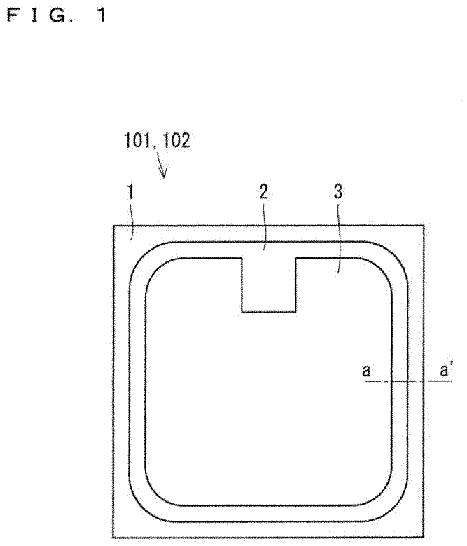

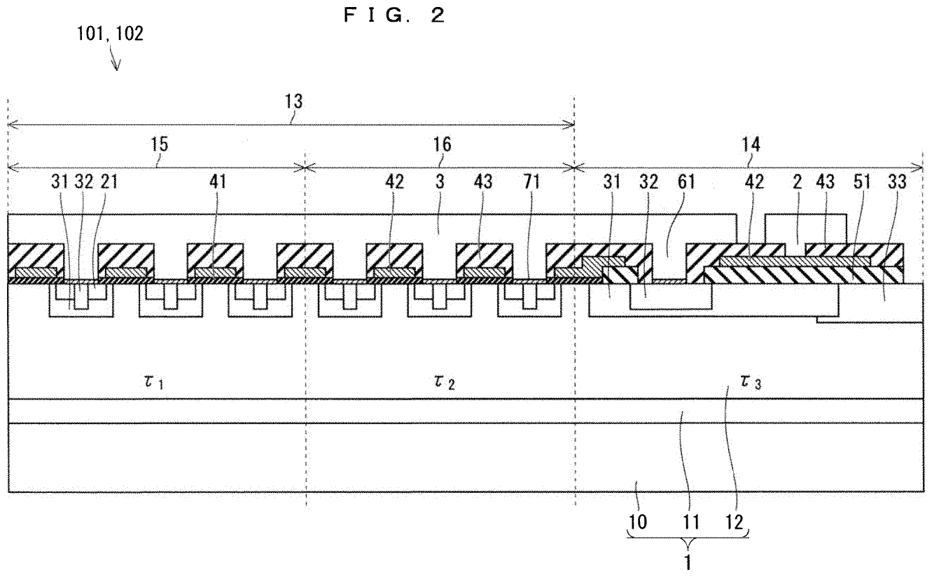

FIG. 1 illustrates a top view of a SiC-MOSFET 101 that is a silicon carbide semiconductor device according to Embodiment 1. FIG. 2 illustrates a cross-sectional view of the SiC-MOSFET 101 taken along the line a-a′ of FIG. 1. In this DESCRIPTION, a MOSFET using a silicon carbide (SiC) substrate as a base material is referred to as a SiC-MOSFET.

As illustrated in FIG. 1, the SiC-MOSFET 101 includes a SiC epitaxial substrate 1, a gate pad 2, and a source pad 3. The gate pad 2 is formed on the SiC epitaxial substrate 1. An external control circuit applies a gate voltage to a center portion of the gate pad 2. The source pad 3 is formed on the gate pad 2.

As illustrated in FIG. 2, the SiC epitaxial substrate 1 includes a SiC substrate 10 of the first conductivity type, a buffer layer 11 of the first conductivity type, and a drift layer 12 of the first conductivity type. The buffer layer 11 and the drift layer 12 are epitaxially grown in this order on one side of the SiC substrate 10 in a thickness direction.

The buffer layer 11 has advantages of recombining holes injected from the device surface side, and reducing a density of holes reaching the SiC substrate 10. The buffer layer 11 may have a function of converting a basal plane dislocation in the SiC substrate 10 into an edge dislocation. The buffer layer 11 need not be a single layer but may have a laminated structure of a plurality of layers. As the impurity concentration of the buffer layer 11 is higher, the buffer layer 11 has a higher capability of preventing expansion of stacking faults for a passing current. Thus, the impurity concentration and the thickness of the buffer layer 11 are set by a density of the current to be passed to the device. For example, the buffer layer 11 preferably has an impurity concentration ranging from 1×10¹⁸ cm⁻³ to 1×10¹⁹ cm⁻³.

The drift layer 12 is formed on one side of the buffer layer 11 in the thickness direction. The drift layer 12 is lower in impurity concentration than the SiC substrate 10 and the buffer layer 11, and should have an impurity concentration lower than or equal to 5×10¹⁶ cm⁻³.

The SiC-MOSFET 101 is classified into an active region 13 in the center, and a breakdown voltage support region 14 around a periphery of the active region 13 in a plan view. The active region 13 is further classified into a first active region 15 in the center, and a second active region 16 between the first active region 15 and the breakdown voltage support region 14. In other words, the second active region 16 is a region closer to the breakdown voltage support region 14 in the active region 13. The width of the second active region 16, that is, the length of the second active region 16 in the horizontal direction on the plane of the paper in FIG. 2 is at least 10 μm or more. The lifetime of minority carriers in the second active region 16 is shorter than that in the first active region 15. Here, τ1, τ2, and τ3 denote the lifetimes of minority carriers in the first active region 15, the second active region 16, and the breakdown voltage support region 14, respectively.

A structure of the active region 13 will be described. A plurality of well regions 31 of the second conductivity type are formed in the surface layer of the drift layer 12 in the active region 13. The well regions 31 are spaced apart from one another. A well contact region 32 of the second conductivity type whose impurity concentration is relatively higher is formed in the center of the surface layer of each of the well regions 31. The well contact region 32 functions as reducing a contact resistance with a metal electrode. In the surface layer of each of the well regions 31, a source region 21 that is an impurity region of the first conductivity type is formed around the well contact region 32.

A gate insulating film 41 is formed across the source regions 21 in adjacent two of the well regions 31. A gate electrode 42 and an interlayer insulating film 43 are formed on the gate insulating film 41. An ohmic electrode 71 is formed on each of the well contact regions 32. The ohmic electrodes 71 connect the source pad 3 to the well contact regions 32. Although FIG. 2 illustrates the gate electrodes 42 of the planar type, the gate electrodes 42 may be of the trench type. Specifically, each of the gate electrodes 42 faces the well region 31 through the gate insulating film 41.

The well regions 31 and the source regions 21 form the p-n junctions in the active region 13. The active region 13 is defined as a region through which a current flows with application of a voltage to the SiC-MOSFET 101.

Next, a structure of the breakdown voltage support region 14 will be described. The well region 31 and the well contact region 32 are also formed in the breakdown voltage support region 14, similarly to the active region 13, A JTE region 33 of the second conductivity type is formed around the periphery of the well region 31 in the breakdown voltage support region 14. The JTE region 33 supports the breakdown voltage of a semiconductor device. One of the examples is a field limiting ring (FLR) structure of forming a ring around the periphery of the semiconductor device. The innermost JTE region 33 in the plan view of the SiC-MOSFET 101 is connected to the outermost well region 31 in the same plan view.

A field insulating film 51 is formed on the well region 31 in the breakdown voltage support region 14. The gate electrode 42 is formed on the field insulating film 51. Furthermore, the interlayer insulating film 43 is formed to cover the gate electrode 42. The interlayer insulating film 43 has an opening for exposing the gate electrode 42. The gate electrode 42 is electrically connected through this opening to the gate pad 2 on the interlayer insulating film 43.

The well region 31 and the drift layer 12 form the p-n junction in the breakdown voltage support region 14, The breakdown voltage support region 14 is a region for supporting the breakdown voltage of the semiconductor device. The JTE region 33 is formed around the active region 13 in the plan view of the SiC-MOSFET 101.

The lifetimes τ2 and τ3 of minority carriers in the second active region 16 and the breakdown voltage support region 14 are shorter than the lifetime τ1 of minority carriers in the first active region 15 in the SiC-MOSFET 101.

### A-2. Manufacturing Method

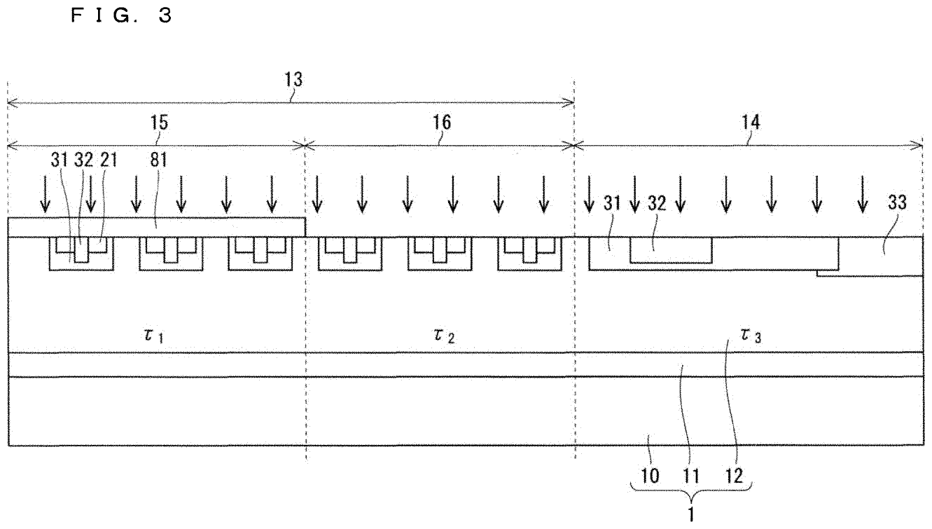

Next, a method for manufacturing the SiC-MOSFET 101 will be described. FIG. 3 is a cross-sectional view illustrating a manufacturing process of the SiC-MOSFET 101. Although the first conductivity type is n-type and the second conductivity type is p-type in the following description, the conductivity types may be reversed.

First, the SiC substrate 10 of n-type and low resistance is prepared. The SiC substrate 10 is a (0001) plane whose first main surface in one plane direction has an off angle, and has a 4H polytype. Then, the buffer layer 11 of n-type is epitaxially grown on the SiC substrate 10 with a desired thickness by chemical vapor deposition (CVD). The buffer layer 11 has an n-type impurity concentration ranging from 1×10¹⁸ cm⁻³ to 1×10¹⁹ cm⁻³, and is, for example, 5 μm thick.

Next, the drift layer 12 made of n-type SiC is epitaxially grown on the buffer layer 11. The drift layer 12 has an n-type impurity concentration ranging from 1×10¹⁴ cm⁻³ to 5×10¹⁶ cm⁻³. The drift layer 12 is 5 to 100 μm thick, for example, 10 μm thick.

Next, an implantation mask is formed in a partial region on the surface of the drift layer 12 using, for example, a photoresist. Then, p-type impurities such as aluminum (Al) are ion-implanted. Here, the depth of the ion-implanted Al approximately ranges from 0.3 to 3 μm, which does not exceed the thickness of the drift layer 12. The ion-implanted Al has an impurity concentration ranging from 1×10¹⁷ cm⁻³ to 1×10¹⁹ cm⁻³, which is higher than that of the drift layer 12. Then, the implantation mask is removed. With this process, the regions into which Al ions have been implanted become the well regions 31.

Next, an implantation mask is formed in a partial region on the surface of the drift layer 12 in the breakdown voltage support region 14 using, for example, a photoresist. Then, p-type impurities such as Al are ion-implanted. Here, the depth of the ion-implanted Al approximately ranges from 0.3 to 3 μm, which does not exceed the thickness of the drift layer 12. The ion-implanted Al has an impurity concentration ranging from 1×10¹⁶ cm⁻³ to 1×10¹⁸ cm⁻³, which is higher than that of the drift layer 12 and lower than that of the well regions 31. Then, the implantation mask is removed. With this process, the region into which Al has been ion-implanted becomes the JTE region 33. Likewise, ion-implanting Al into a partial region in each of the well regions 31 with an impurity concentration higher than that of the well regions 31 forms the well contact regions 32.

Then, an implantation mask is formed using, for example, a photoresist so that a partial region inside each of the well regions 31 in the active region 13 is opened. Then, n-type impurities such as nitrogen (N) are ion-implanted. The depth of the ion-implanted N is less than the thickness of the well region 31. The ion-implanted N has an impurity concentration ranging from 1×10¹⁸ cm⁻³ to 1×10²¹ cm⁻³, which exceeds the p-type impurity concentration of the well regions 31. N-type regions in the regions where N has been implanted in this process become the source regions 21.

Next, a lifetime adjustment process is performed so that the lifetimes τ2 and τ3 of minority carriers in the second active region 16 and the breakdown voltage support region 14 are made shorter than the lifetime τ1 of minority carriers in the first active region 15. Specifically, an implantation mask 81 is formed on the surface of the drift layer 12 in the first active region 15 using, for example, a photoresist or an oxidized film as illustrated in FIG. 3. Then, ions of an inert element are irradiated so that recombination centers are introduced into the second active region 16 and the breakdown voltage support region 14. Although the implantation mask 81 is formed only in the first active region 15 in FIG. 3, the implantation mask 81 may be formed in the breakdown voltage support region 14 in addition to the first active region 15. Specifically, the implantation mask 81 should be formed at least in the first active region 15. The inert element to be irradiated in this process is, for example, He or Ar. The implantation energy preferably ranges from 10 keV to 10 MeV. The irradiated ions form crystal defects in a region into which the ions have been implanted in this process. The formed crystal defects function as recombination centers of holes and electrons. Thus, the region into which the ions have been implanted is higher in probability of recombining holes and electrons and shorter in carrier lifetime than a region into which no ion is implanted. Thereby, the lifetimes τ2 and τ3 of minority carriers in the second active region 16 and the breakdown voltage support region 14 are shorter than the lifetime τ1 of minority carriers in the first active region 15.

Next, a thermal processing device performs annealing in an inert gas atmosphere such as argon (Ar) at a temperature from 1300° C. to 1900° C. for 30 seconds to 1 hour. This annealing electrically activates the ion-implanted N and Al, and simultaneously recovers SiC crystals excessively damaged by irradiation of He ions.

Then, the field insulating film 51 made of silicon oxide and having a thickness from 0.3 μm to 2 μm is formed by, for example, CVD or a photolithography technique on the well region 31 in the breakdown voltage support region 14.

Next, the surface of silicon carbide that is not covered with the field insulating film 51 is thermally oxidized to form a silicon oxide film with a desired thickness as the gate insulating film 41. Then, a polycrystalline silicon film having conductivity is formed by low pressure CVD on the gate insulating film 41 and the field insulating film 51, and is patterned to form the gate electrode 42. Next, the interlayer insulating film 43 made of silicon oxide is formed by low pressure CVD. Then, a contact hole 61 is formed through the interlayer insulating film 43 and the gate insulating film 41 to reach the well contact region 32 and the well region 31.

Next, a metal film mainly containing Ni is formed by, for example, sputtering. Then, the metal film is subjected to a thermal process at a temperature from 600° C. to 1100° C. so that the metal film mainly containing Ni reacts with a silicon carbide layer in the contact hole 61, thereby forming a silicide between the silicon carbide layer and the metal film. Next, the residual metal film other than the silicide resulting from the reaction is removed by wet etching. The residual silicide becomes the ohmic electrodes 71. Then, a metal film mainly containing Ni is formed on the rear surface (second main surface) of the SiC substrate 10 and thermally processed, thereby forming a rear surface ohmic electrode (not illustrated) on the rear side of the SiC substrate 10.

Then, a wiring metal made of, for example, Al is formed by sputtering or vapor deposition on the surface of the substrate being processed so far, and is processed into a predetermined shape by a photolithographic technique. This forms the source pad 3 in contact with the ohmic electrodes 71, and the gate pad 2 in contact with the gate electrode 42. Thereby, the SiC-MOSFET 101 is obtained.

A method for manufacturing the SiC-MOSFET 101 includes: forming the buffer layer 11 of n-type on the SiC substrate 10 of n-type; forming the drift layer 12 of n-type on the buffer layer 11; forming a plurality of the well regions 31 of p-type in a surface layer of the drift layer 12, the plurality of well regions 31 being spaced apart from one another, wherein a structure including the SiC substrate 10, the buffer layer 11, and the drift layer 12 is classified into the active region 13, and the breakdown voltage support region 14 around a periphery of the active region 13 in a plan view, and the active region 13 is classified into the first active region 15 in a center portion, and the second active region 16 between the first active region 15 and the breakdown voltage support region 14 in the plan view, forming the source region 21 that is an impurity region of n-type in a surface layer of each of the well regions 31 in the active region 13; and ion-implanting inert elements into the second active region 16 and the breakdown voltage support region 14 to introduce recombination centers.

Since the second active region 16 and the breakdown voltage support region 14 are simultaneously irradiated with the inert elements through one-time ion implantation processes in the description above, the lifetimes τ2 and τ3 of minority carriers in the second active region 16 and the breakdown voltage support region 14 are the same value. However, the ion implantation processes using the inert elements may be divided into two, so that the breakdown voltage support region 14 and the second active region 16 may be irradiated with the inert elements at different timings.

Specifically, an implantation mask is formed on the surface of the drift layer 12 in the first active region 15 and the breakdown voltage support region 14. Then, ions of an inert element are irradiated for the first time. The implantation energy preferably ranges from 10 keV to 10 MeV. The irradiated ions form crystal defects in the second active region 16 into which ions have been implanted in this process.

Then, the implantation mask is removed from the surface of the drift layer 12 in the first active region 15 and the breakdown voltage support region 14. Next, an implantation mask is formed on the surface of the drift layer 12 in the first active region 15 and the second active region 16. Then, ions are irradiated for the second time to introduce a recombination center. Although the ions to be irradiated are identical to those irradiated for the first time, the amount of the second irradiation is set larger than the first one. This allows the breakdown voltage support region 14 to be irradiated with many more ions than the second active region 16. As a result, more crystal defects are formed in the breakdown voltage support region 14. Thus, the lifetime τ3 of minority carriers in the breakdown voltage support region 14 is shorter than the lifetime τ2 of minority carriers in the second active region 16. Specifically, the lifetimes of minority carriers satisfy τ3<τ2<τ1.

### A-3. Advantages

The lifetimes of minority carriers in the breakdown voltage support region 14, the first active region 15, and the second active region 16 can be measured by a microwave photoconductivity decay (hereinafter referred to as μ-PCD) method. The μ-PCD method is a method for contactlessly and nondestructively measuring the carrier lifetime from the time variation in the microwave reflectivity. Pulsing the laser onto the SiC epitaxial substrate 1 generates excess carriers (majority carriers and minority carriers). After the lifetime defined by a physical property of the SiC epitaxial substrate 1 such as a defect density or an impurity concentration, the excess carriers recombine and disappear. The lifetime is measured from the variation in the microwave reflectivity. Suppose that generated excess carriers are expressed by 1, the lifetime of minority carriers is the time when the excess carriers are reduced to 1/e.

Besides, the lifetime of minority carriers can be measured by, for example, photo luminescence.

As a result of the research, the Inventors have found that application of a current larger than or equal to 500 A/cm² to a body diode of a SiC-MOSFET generates, in a boundary between the active region 13 and the breakdown voltage support region 14, a region whose hole current density is more than double that of the center of the active region 13 at the maximum and that stacking faults occur preferentially in the boundary region.

Making the lifetimes τ2 and τ3 of minority carriers in the second active region 16 and the breakdown voltage support region 14 shorter than the lifetime τ1 of minority carriers in the first active region 15 in the SiC-MOSFET 101 can prevent the concentration of the hole current in the boundary between the active region 13 and the breakdown voltage support region 14, without significantly damaging the characteristics of the body diode even with application of the large current. Thus, the stacking faults generated from the SiC substrate 10 can be prevented in the boundary between the active region 13 and the breakdown voltage support region 14. Furthermore, the buffer layer 11 for preventing the stacking faults can be thinned.

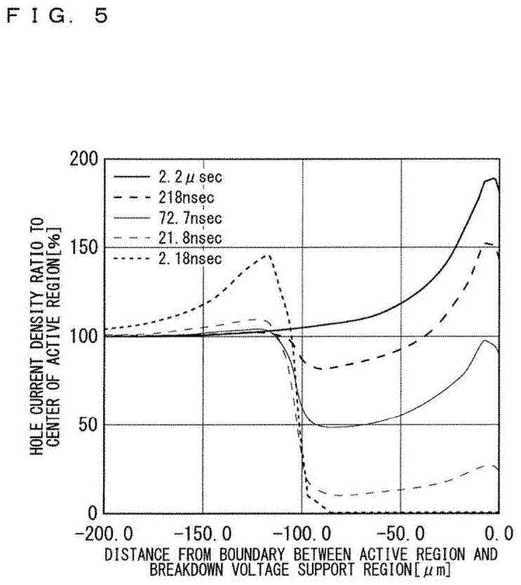

FIG. 5 illustrates a simulation result of the hole current density distribution when a p-n diode replaces the active region 13 in the SiC-MOSFET 101 and the second active region 16 is 100 μm wide. The Inventors have confirmed that an MOSFET and a p-n diode used as the active regions 13 have the same tendency in the result of the hole current density distribution. In this simulation, when the applied current was 1000 A/cm², the lifetimes τ2 and τ3 of minority carriers in the second active region 16 and the breakdown voltage support region 14 were changed from 2.2 μs to 218 ns, 72.7 ns, 21.8 ns, and 2.18 ns, where τ2=τ3. Here, τ1 was 2.2 μs. The vertical axis represents a ratio of a hole current density in the boundary between the active region 13 and the breakdown voltage support region 14 to a hole current density in the center of the active region 13. When the chip circumferential direction (the right direction on the plane of the paper in FIG. 2) is a positive direction, the horizontal axis represents a distance from the boundary between the active region 13 and the breakdown voltage support region 14 with respect to the boundary as the origin. A range from −200 μm to −100 μm in the horizontal axis corresponds to the first active region 15. A range from −100 μm to 0 μm in the horizontal axis corresponds to the second active region 16. The hole current density is a value in the top surface of the SiC substrate 10.

FIG. 5 illustrates that the concentration of the hole current generated in the boundary between the active region 13 and the breakdown voltage support region 14 can be resolved as the lifetimes τ2 and τ3 of minority carriers in the second active region 16 and the breakdown voltage support region 14 become shorter. FIG. 5 also clarifies that the hole current concentrates on a boundary between the first active region 15 and the second active region 16 when the lifetimes τ2 and τ3 of minority carriers in the second active region 16 and the breakdown voltage support region 14 excessively decrease. Accordingly, the lifetime τ2 of minority carriers in the second active region 16 and the breakdown voltage support region 14 preferably ranges from 1 ns to 500 ns, more preferably from 10 ns to 100 ns to resolve the concentration of the hole current. Typically, the lifetime τ1 of minority carriers in the first active region 15 ranges from 1 μs to 10 μs. Thus, the lifetimes τ2 and τ3 of minority carriers in the second active region 16 and the breakdown voltage support region 14 preferably range from 1/1000 to 1/10 of the lifetime τ1 of minority carriers in the first active region 15.

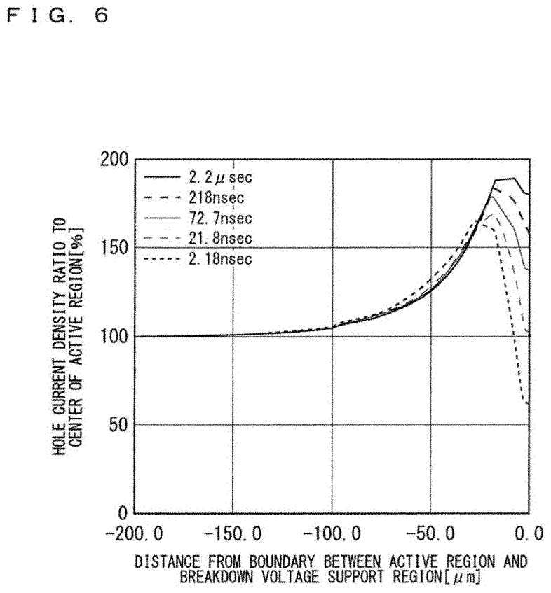

FIG. 6 illustrates a simulation result of the hole current density distribution when a p-n diode replaces the active region 13 in the SiC-MOSFET 101 and the second active region 16 is 0 μm wide, that is, the second active region 16 is not formed but only the breakdown voltage support region 14 is formed as a low lifetime region. The Inventors have confirmed that an MOSFET and a p-n diode used as the active regions 13 have the same tendency in the result of the hole current density distribution. Other simulation conditions are identical to those in FIG. 5. FIG. 6 clarifies that shortening the lifetime τ3 of minority carriers in the second active region 16 produces a little effect on resolving the concentration of the hole current in the boundary between the active region 13 and the breakdown voltage support region 14.

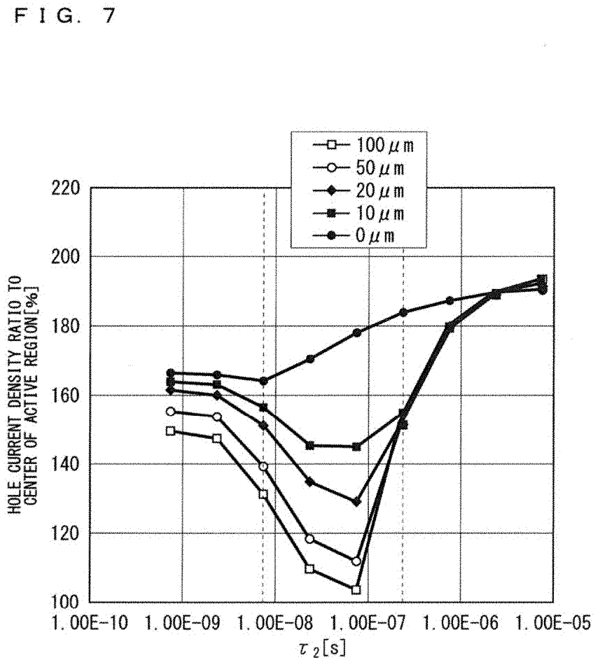

FIG. 7 illustrates a ratio of a hole current density in the vicinity of the boundary between the active region 13 and the breakdown voltage support region 14 to a hole current density in the center of the active region 13 when the width of the second active region 16 and the lifetime of minority carriers in the second active region 16 are changed. FIG. 7 clarifies that the hole current density in the vicinity of the boundary between the active region 13 and the breakdown voltage support region 14 takes the minimum value when the second active region 16 is 10 μm wide or more and the lifetime τ2 of minority carriers in the second active region 16 ranges from 10 nsec to 100 nsec. This clarifies that the width of the second active region 16 and the lifetime of minority carriers in the second active region 16 have appropriate values.

These results show that the second active region 16 with a shorter lifetime of minority carriers can resolve the concentration of the hole current generated in the boundary between the active region 13 and the breakdown voltage support region 14.

The SiC-MOSFET 101 according to Embodiment 1 includes: the SiC substrate 10 of the first conductivity type; the buffer layer 11 of the first conductivity type which is formed on the SiC substrate 10; the drift layer 12 of the first conductivity type which is formed on the buffer layer 11; and the well region 31 of the second conductivity type which is formed in a surface layer of the drift layer 12. A structure including the SiC substrate 10, the buffer layer 11, and the drift layer 12 is classified into the active region 13 through which a current flows with application of a voltage to the SiC-MOSFET 101, and the breakdown voltage support region 14 around a periphery of the active region 13 in a plan view. The active region 13 is classified into the first active region 15 in a center portion, and the second active region 16 between the first active region 15 and the breakdown voltage support region 14 in the plan view. At least the second active region 16 and the breakdown voltage support region 14 among the first active region 15, the second active region 16, and the breakdown voltage support region 14 contain inert elements. The SiC-MOSFET 101 further includes the source region 21 that is an impurity region of the first conductivity type and is formed in a surface layer of the well region 31 in the active region 13. The inert elements in the second active region 16 and the breakdown voltage support region 14 are higher in ion concentration than an inert element in the first active region 15. The inert elements introduce recombination centers into the second active region 16 and the breakdown voltage support region 14. Thereby, the lifetimes τ2 and τ3 of minority carriers decrease and become shorter than the lifetime τ1 of minority carriers in the first active region 15. This can prevent the concentration of the hole current in the boundary between the active region 13 and the breakdown voltage support region 14 with application of a large current to a body diode. Since the buffer layer 11 need not be formed thicker, the productivity of the SiC-MOSFET 101 is superior.

### B. Embodiment 2

### B-1. Structure

As illustrated in FIGS. 1 and 2, a structure of a SiC-MOSFET 102 that is a silicon carbide semiconductor device according to Embodiment 2 is the same as that of the SiC-MOSFET 101 according to Embodiment 1. The SiC-MOSFET 101 achieves τ1>τ2 by reducing the lifetime τ2 of minority carriers in the second active region 16 through implantation of ions of an inert element into the second active region 16. In addition to the characteristics of the SiC-MOSFET 101, the SiC-MOSFET 102 produces an advantage of improving the element resistance of the body diode by extending the lifetime τ1 of minority carriers in the first active region 15 besides the advantage of the SiC-MOSFET 101.

### B-2. Manufacturing Method

A method for manufacturing the SiC-MOSFET 102 will be described. The method for manufacturing the SiC-MOSFET 102 is the same as that of the SiC-MOSFET 101 up to the formation of the source region 21.

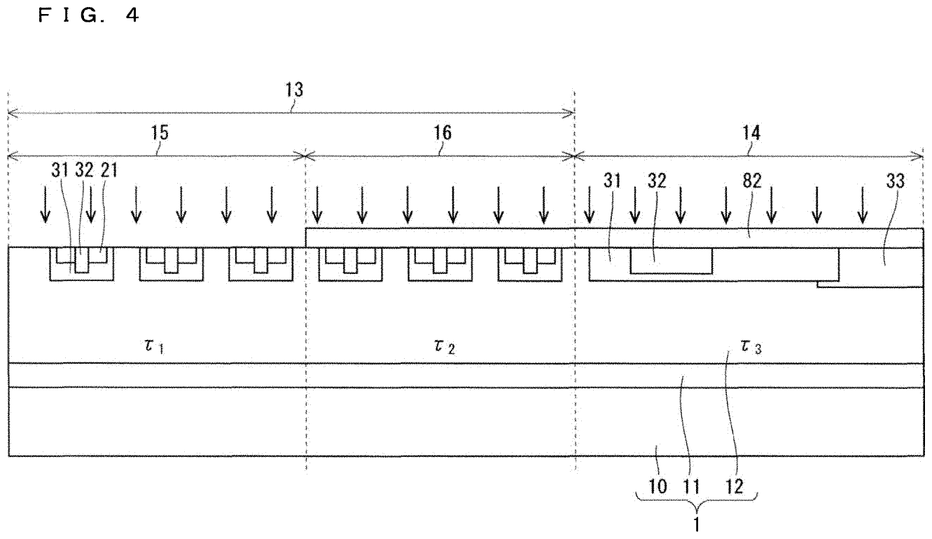

After the source region 21 is formed, an implantation mask 82 is formed on the surface of the drift layer 12 in the second active region 16 and the breakdown voltage support region 14 using, for example, a photoresist or an oxidized film as illustrated in FIG. 4. Then, carbon atoms are ion-implanted. Although the implantation mask 82 is formed in the second active region 16 and the breakdown voltage support region 14 in FIG. 4, the implantation mask 82 need not be formed in the breakdown voltage support region 14. Here, a density of the ion-implanted carbon atoms on the implanted surface preferably ranges from 1×10¹³ cm⁻² to 1×10¹⁶ cm⁻². The implantation energy preferably ranges from 10 keV to 10 MeV. This process allows the carbon atoms to be ion-implanted into the first active region 15 and to be interstitially introduced in a SiC epitaxial crystal.

Next, the second active region 16 and the breakdown voltage support region 14 are irradiated with He ions or Ar ions, so that recombination centers are introduced. This process is the same as that illustrated in FIG. 3 according to Embodiment 1. This process reduces the lifetimes τ2 and τ3 of minority carriers in the second active region 16 and the breakdown voltage support region 14. Thus, the lifetimes τ2 and τ3 are shorter than the lifetime τ1 of minority carriers in the first active region 15.

Although the recombination centers are introduced after the implantation of carbon atoms, the order of these processes may be reversed.

Next, a thermal processing device performs annealing in an inert gas atmosphere such as argon (Ar) at a temperature from 1300° C. to 1900° C. for 30 seconds to 1 hour. This annealing electrically activates the ion-implanted N and Al. At the same time, SiC crystals excessively damaged by irradiation of He ions are recovered. Furthermore, the interstitial carbon atoms react with carbon vacancies that are sort of point defects in the drift layer 12. This reduces the point defects in the first active region 15 into which the interstitial carbon atoms have been implanted. Reduction in traps of minority carriers caused by the point defects increases the lifetime τ1 of minority carriers in the first active region 15.

Then, the field insulating film 51, the gate insulating film 41, the gate electrode 42, the interlayer insulation film 43, the ohmic electrodes 71, the source pad 3, and the gate pad 2 are formed similarly to Embodiment 1, thus completing the SiC-MOSFET 102.

### B-3. Advantages

In the SiC-MSF ET 102 according to Embodiment 2, the first active region 15 is higher in carbon concentration than the second active region 16 and the breakdown voltage support region 14. This increases the lifetime ii of minority carriers in the first active region 15, and enhances the effect of conductivity modulation in the drift layer 12. Thus, the SiC-MOSFET 102 has an advantage of reducing the element resistance of the body diode in addition to the advantages of Embodiment 1.

The lifetime τ2 of minority carriers in the second active region 16 need not be longer than the lifetime τ3 of minority carriers in the breakdown voltage support region 14.

The technologies disclosed in Embodiments of this DESCRIPTION can be freely combined, or appropriately modified or omitted within the scope of the advantages that the technologies bring.

### EXPLANATION OF REFERENCE SIGNS

1 SiC epitaxial substrate, 2 gate pad, 3 source pad, 10 SiC substrate, 11 buffer layer, 12 drift layer, 13 active region, 14 breakdown voltage support region, 15 first act region, 16 second active region, 21 source region, 31 well region, 32 well contact region, 33 JTE region, 41 gate insulating film, 42 gate electrode, 43 interlayer insulating film, 51 field insulating film, 61 contact hole, 71 ohmic electrode, 81, 82 implantation mask.

1. A silicon carbide semiconductor device, comprising:
a silicon carbide substrate of a first conductivity type;
a buffer layer of the first conductivity type, the buffer layer being formed on the silicon carbide substrate;
a drift layer of the first conductivity type, the drift layer being formed on the buffer layer;
a well region of a second conductivity type, the well region being formed in a surface layer of the drift layer;
a source region that is an impurity region of the first conductivity type, the source region being formed in a surface layer of the well region; and
a source pad electrically connected to the source region,
wherein a structure including the silicon carbide substrate, the buffer layer, and the drift layer is classified into an active region through which a current flows with application of a voltage to the silicon carbide semiconductor device, and a breakdown voltage support region around a periphery of the active region in a plan view,
the active region is classified into a first active region in a center portion, and a second active region between the first active region and the breakdown voltage support region in the plan view,
the source pad covers the first active region and the second active region, and
lifetimes of minority carriers in the second active region and the breakdown voltage support region are shorter than a lifetime of minority carriers in the first active region.

2. The silicon carbide semiconductor device according to claim 1,
wherein the lifetimes of the minority carriers in the second active region and the breakdown voltage support region range from 1 ns to 500 ns.

3. The silicon carbide semiconductor device according to claim 1,
wherein the lifetimes of the minority carriers in the second active region and the breakdown voltage support region range from 1/1000 to 1/10 of the lifetime of the minority carriers in the first active region.

4. The silicon carbide semiconductor device according to claim 1,
wherein the second active region is 10 μm wide or more.

5. The silicon carbide semiconductor device according to claim 1,
wherein the buffer layer has an impurity concentration ranging from 1×10¹⁸ cm⁻³ to 1×10¹⁹ cm⁻³.

6. The silicon carbide semiconductor device according to claim 1,
wherein the drift layer has an impurity concentration lower than or equal to 5×10¹⁶ cm⁻³.

7. The silicon carbide semiconductor device according to claim 1,
wherein the first active region is higher in carbon concentration than the second active region and the breakdown voltage support region.

8. A silicon carbide semiconductor device, comprising:
a silicon carbide substrate of a first conductivity type;
a buffer layer of the first conductivity type, the buffer layer being formed on the silicon carbide substrate;
a drift layer of the first conductivity type, the drift layer being formed on the buffer layer;
a well region of a second conductivity type, the well region being formed in a surface layer of the drift layer;
a source region that is an impurity region of the first conductivity type, the source region being formed in a surface layer of the well region; and
a source pad electrically connected to the source region,
wherein a structure including the silicon carbide substrate, the buffer layer, and the drift layer is classified into an active region through which a current flows with application of a voltage to the silicon carbide semiconductor device, and a breakdown voltage support region around a periphery of the active region in a plan view,
the active region is classified into a first active region in a center portion, and a second active region between the first active region and the breakdown voltage support region in the plan view,
the source pad covers the first active region and the second active region,
at least the second active region and the breakdown voltage support region among the first active region, the second active region, and the breakdown voltage support region contain inert elements, and
the inert elements in the second active region and the breakdown voltage support region are higher in ion concentration than an inert element in the first active region.

9. A method for manufacturing a silicon carbide semiconductor device, the method comprising:
forming a buffer layer of a first conductivity type on a silicon carbide substrate of the first conductivity type;
forming a drift layer of the first conductivity type on the buffer layer;
forming a plurality of well regions of a second conductivity type in a surface layer of the drift layer, the plurality of well regions being spaced apart from one another;
forming a source region that is an impurity region of the first conductivity type, in a surface layer of each of the well regions;
forming a source pad electrically connected to the source region; and
wherein a structure including the silicon carbide substrate, the buffer layer, and the drift layer is classified into an active region, and a breakdown voltage support region around a periphery of the active region in a plan view,
the active region is classified into a first active region in a center portion, and a second active region between the first active region and the breakdown voltage support region in the plan view, and
the source pad covers the first active region and the second active region,
ion-implanting inert elements into the second active region and the breakdown voltage support region to introduce recombination centers.

10. The silicon carbide semiconductor device according to claim 1,
wherein the source pad covers a part of the breakdown voltage support region.
